(19) United States
(12) Patent Application Publication
(10) Pub. No.: US 2012/0153944 A1
(43) Pub. Date: Jun. 21, 2012

(54) METHOD FOR INSPECTING AN AUSTENITIC STAINLESS STEEL WELD

(75) Inventors: Toyokazu Tada, Niihama-shi (JP); Hidehiko Suetsugu, Niihama-shi (JP)

(73) Assignee: SUMITOMO CHEMICAL COMPANY, LIMITED, Tokyo (JP)

(21) Appl. No.: 13/392,088

(22) PCT Filed: Aug. 25, 2010
(86) PCT No.: PCT/JP2010/064856

§ 371 Date: Feb. 23, 2012

(30) Foreign Application Priority Data
Aug. 26, 2009 (JP) 2009-195304

(51) Int. Cl. G01R 33/12

(52) U.S. Cl. 324/239

(57) ABSTRACT

An object of the present invention is to provide a method for inspecting the presence or absence of a foreign metallic material mixed into an austenitic stainless steel material weld with more satisfactory accuracy.

The method for inspecting an austenitic stainless steel weld of the present invention is characterized by comprises performing eddy current test of a weld portion of an austenitic stainless steel using a probe comprising an excitation and inspection coil and a permanent magnet disposed inside the excitation and inspection coil, and inspecting the presence or absence of a foreign metallic material mixed into the weld portion, and is also characterized in that magnetic flux density of magnetic field formed by the permanent magnet is from about 0.3 to about 1.5 tesla.

### TECHNICAL FIELD

The present invention relates to a method for inspecting an austenitic stainless steel weld. More particularly, the present invention relates to a method for detecting a foreign (dissimilar) metallic material mixed into an austenitic stainless steel weld with more satisfactory accuracy.

### BACKGROUND ART

Usually, a foreign metallic material is not mixed into a weld portion of austenitic stainless steel. However, because of insufficient quality control during welding, for example, a weld metal made of carbon steel is sometimes mixed into the weld portion to cause a problem later. When carbon steel is mixed into an outer surface of the weld portion, it is possible to easily detect the carbon steel by a magnet test. However, when the carbon steel is mixed into inside the weld portion such as first layer of the weld portion, it is difficult to detect the carbon steel.

It has widely been performed to inspect the presence of defects by performing eddy current test of a weld portion of metal using a probe for surface type eddy current test, comprising an excitation and inspection coil and a balance coil (see, for example, Patent Document 1, Patent Document 2).

However, sufficient accuracy of inspection can not be obtained always by using this method because δ-ferrite an excess weld portion (weld reinforcement) of the weld portion is detected as a defect in error and other reasons. Thus, a new inspection method showing higher accuracy has been desired.

### PRIOR ART DOCUMENTS

### Patent Documents

Patent Document 1: JP H08-101169A
Patent Document 2: JP 2005-201779A

### SUMMARY OF THE INVENTION

### Technical Problem

An object of the present invention is to provide an inspection method for detecting a foreign metallic material mixed into an austenitic stainless steel material weld with more satisfactory accuracy.

### Solution to Problem

The inventors of the present invention have intensively studied about a inspecting method for detecting a foreign metallic material mixed into an austenitic stainless steel weld and found that it is possible to remove an influence of δ-ferrite and to inspect the presence or absence of a foreign metallic material mixed into an austenitic stainless steel weld with more satisfactory accuracy by performing eddy current test of a weld portion of austenitic stainless steel using a probe comprising an excitation and inspection coil (inspection coil) and a permanent magnet disposed inside the excitation and inspection coil, thus leading to the present invention.

The present invention provides a method for inspecting an austenitic stainless steel weld, which comprises performing eddy current test (eddy current examination) of a weld portion of an austenitic stainless steel using a probe comprising an excitation and inspection coil (exciting and inspecting coil) and a permanent magnet disposed inside the excitation and inspection coil, thereby detecting the presence or absence of a foreign metallic material mixed into the weld portion.

### Advantageous Effects of Invention

According to the method of the present invention, it is possible to detect the presence or absence of a foreign metallic material mixed into an austenitic stainless steel weld with more satisfactory accuracy.

### BRIEF DESCRIPTION OF THE DRAWINGS

FIG. 1 is a view for explaining the principle of an eddy current test method.

FIG. 2 is another view for explaining the principle of an eddy current test method.

FIG. 3 is a schematic sectional view showing one embodiment of a probe of the present invention.

FIG. 4 is a schematic sectional view showing one embodiment of a probe that has conventionally been used.

FIG. 5 is a graph showing one example of a master plot diagram.

### DESCRIPTION OF EMBODIMENTS

A foreign metallic material contained in an austenitic stainless steel material weld is not particularly limited as long as it is a ferromagnetic material, but may be carbon steel with high possibility. Therefore, a description will be made below by way of carbon steel as an example.

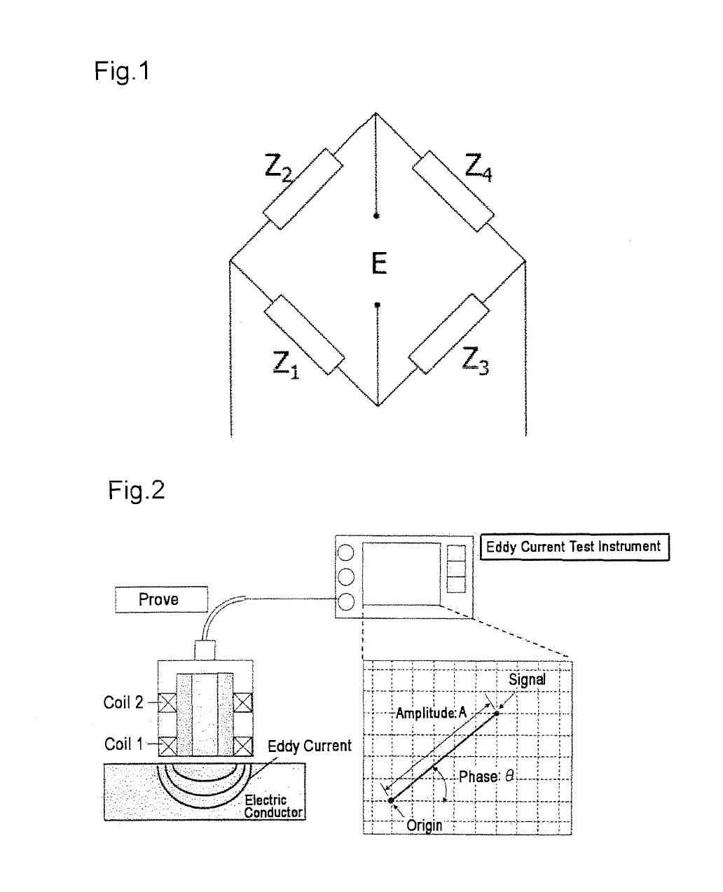

FIG. 1 and FIG. 2 are view for explaining the principle of an eddy current test method. Two coils (impedances thereof are Z₁ and Z₂) of an excitation and inspection coil (for example, a coil 1 in FIG. 2) and a balance coil (for example, a coil 2 in FIG. 2) provided in a probe as well as two variable resistances (resistances thereof are Z₃ and Z₄) provided in an eddy current test instrument form a Wheatstone bridge.

For example, when two coils are present in air, E is set at 0 by adjusting variable resistances Z₃ and Z₄. Next, when the excitation and inspection coil is allowed to approach an electric conductor, the impedance changes, and thus the collapse of balance of the bridge occurs and signal E including information of the electric conductor is outputted. This signal is outputted as an amplitude A and a phase θ.

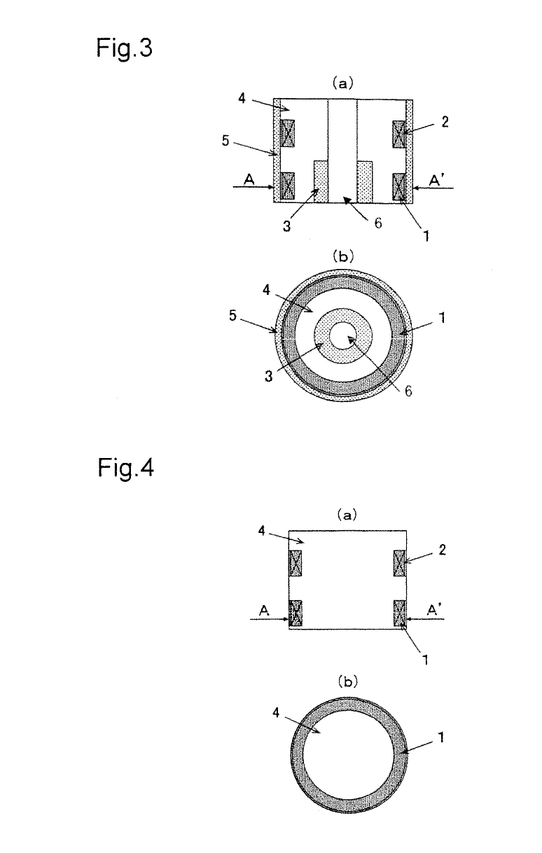

FIG. 3 is a schematic sectional view showing one embodiment of a probe of the present invention. FIG. 3(a) is a sectional view of the side and FIG. 3(b) is sectional view taken along lines A-A′. An excitation and inspection coil 1 and a balance coil 2 are mounted outside a cylindrical bobbin 4, a permanent magnet 3 is mounted inside the cylindrical bobbin 4, and a magnetic shielding 5 is mounted outside the excitation and inspection coil 1 and the balance coil 2. A conducting wire of the coil is not shown.

The magnetic shielding 5 is not necessarily required. However, it is preferred to mount the magnetic shielding 5 so as to prevent noise from generating as a result of exerting an influence of magnetism from the outside and an influence of magnetic field due to a permanent magnet on others.

FIG. 4 is a schematic sectional view showing one embodiment of a probe that has been conventionally been used. An excitation and inspection coil 1 and a balance coil 2 are mounted outside a columnar bobbin 4.

The probe used in the present invention is different from the probe, that has been conventionally been used, in that a permanent magnet is mounted inside the excitation and inspection coil.

A bobbin is formed of polyacetal or the like. The excitation and inspection coil and balance coil is formed, for example, by winding a copper wire having an element wire diameter of about 0.14 to 0.18 mm, about 400 to 600 times, in a length of about 6 to 10 mm.

A high performance permanent magnet such as a neodymium magnet is used, for example, as the permanent magnet. The permanent magnet is, for example, in the from of a cylinder measuring 8 to 12 mm in inner diameter, 15 to 20 mm in outer diameter and 12 to 16 mm in length and, usually, 6 to 10 disk-shaped magnets, each having a thickness of 1.5 to 2 mm, are laid one upon another to obtain a permanent magnet having a length of 12 to 16 mm.

When carbon steel is mixed into an austenitic stainless steel weld, it is preferred to use a permanent magnet that controls magnetic flux density of the magnetic field formed by the permanent magnet within a range from about 0.3 to 1.5 tesla, and preferably from about 0.5 to 1.0 tesla.

Commonly, when the magnetic field applied to ferromagnetic material is increased, relative permeability of the ferromagnetic material increases. When the magnetic field is more increased, the relative permeability decreases and, finally, the magnetic density is saturated and the relative permeability approaches as close as possible to relative permeability of a non-magnetic material by the following reason.

The degree varies depending on the kind of the ferromagnetic material and δ-ferrite of an excess weld portion of the weld portion is likely to be magnetically saturated. In the above magnetic flux density, since δ-ferrite is magnetically saturated and the relative permeability thereof approaches to the relative permeability of austenitic stainless steel, the influence of the δ-ferrite is removed. In contrast, the relative permeability of carbon steel inside the weld portion increases, thereby remarkably increasing an S/N ratio of the probe. In other words, it is considered that it is possible to detect the carbon steel mixed into the weld portion with more satisfactory accuracy without detecting of δ-ferrite.

The magnetic shielding may be formed of a ferromagnetic material such as carbon steel.

The permanent magnet and the coils may be fixed by an acrylic adhesive.

The coil is connected to an eddy current test instrument using a conducting wire and then the presence or absence of a foreign metallic material mixed into a weld portion is inspected by signal processing.

In the present invention, calibration is performed by the above probe using a simulation test material (reference material) in which carbon steel is mixed into an austenitic stainless steel material weld in advance.

First, initial setting of the probe is performed in the air. A test frequency is selected from 0.5 to 1.0 kHz, X-coordinate is set at 0 V as an origin, and Y-coordinate is usually set at about −1.5 V in a minus (−) direction because signal is deflected only in a plus (+) direction of Y. This value is determined based on display and is not limited thereto.

Next, an amplitude and a phase are adjusted by the eddy current test instrument so that the amplitude is usually deflected by a predetermined value 1.5 V, in a +X direction when the probe is placed on a base material (non-weld portion) the simulation test material. It is possible to optimally display, for example, by doubling this value.

At this time, it is necessary that the amplitude value must be increased as the wall thickness of the base material decreases, and the amplitude value decreases as the wall thickness becomes larger. Therefore, the wall thickness of the base material can be estimated.

Under the above conditions, a simulation test material including a sound weld portion and a simulation test material including a weld portion containing carbon steel mixed therein are inspected. In order to discriminate the presence or absence of mixing of the carbon steel based on the measurement results, a master plot diagram is made and a threshold value is set.

With respect to a thin-walled test material having a wall thickness of 3 mm or 4 mm, signal is deflected fully when the weld portion containing the carbon steel mixed therein is measured. Therefore, the amplitude value is decreased each time. For example, it is adjusted by −6 dB or −12 dB.

Actually, detection of the presence or absence of mixing of the carbon steel into an austenitic stainless steel weld is performed in the same manner as in the case of the above calibration.

The same initial setting as that in the case of the calibration of the probe is performed. Next, a probe is placed on a base metal (non-weld portion) of austenitic stainless steel to be inspected, and then an amplitude and a phase are adjusted by the eddy current test instrument so that the amplitude is deflected by the same predetermined value as that in the case of the calibration in a +X direction.

Next, an austenitic stainless steel weld to be inspected is eddy current tested and the presence or absence of mixing of the carbon steel is discriminated using a master plot diagram made in advance.

In the embodiment shown in FIG. 3, both excitation to an electric conductor and inspection of an eddy current of an electric conductor are performed by one coil, namely, an excitation and inspection coil 1. However, the present invention is not limited thereto and includes the embodiment in which inspection is performed by another coil (inspection coil) that is different from a coil to perform the excitation (excitation coil). In this case, a permanent magnet is disposed at least inside the inspection coil.

The present invention will be described below by way of Examples, but the present invention is not limited to the following Examples.

### Example 1

A probe, an eddy current test instrument and a recorder used are as follows.

### (1) Probe

The same probe shown in FIG. 3 was made and used. The materials and shapes used are shown below.

Excitation and inspection coil 1 and balance coil 2: 28 mm in outer diameter×21 mm in inner diameter×8 mm in length, and 0.16 mm in wire diameter of copper coil×500 in number of turns

Permanent magnet 3: 18 mm in outer diameter×12 mm in inner diameter×1.8 mm in thickness×8 pieces

Neodymium magnet NEOMAX®-32H (manufactured by Sumitomo Special Metals. Co., Ltd.)

Magnetic flux density of magnetic field formed by this permanent magnet: about 0.5 tesla

Bobbin: Polyacetal copolymer (manufactured by Polyplastics Co., Ltd.)

Magnetic shielding: Carbon steel

Case: Polyacetal copolymer

Adhesive used to be fixed: Acrylic adhesive Hard Lock® (manufactured by DENKI KAGAKU KOGYO KABUSHIKI KAISHA)

### (2) Eddy Current Test Instrument:

Eddy current test instrument MiniPhasec (manufactured by GE Inspection Technologies)

### (3) Recorder

MEMORY HICORDER 8846 (manufactured by HIOKI E.E. CORPORATION)

A simulation test material was made by butt welding of a thin plate (measuring 100 mm in length×100 mm in width, 3 mm, 4 mm or 5 mm in wall thickness) made of SUS304 (304 stainless steel) and straight pipes 10B sch20s (wall thickness: 6.5 mm) and 6B sch40s (wall thickness: 7.1 mm).

With respect to half of a butt weld portion, the first layer and other layers were formed using TIG308 (corresponding to 308L stainless steel (SUS308L)) as a welding rod (sound part). With respect to remaining half of a butt weld portion, the first layer was formed using TGS50 (corresponding to carbon steel) as a welding rod, and other layers were formed using TIG308 as a welding rod (mixed part).

Using the above probe, eddy current test instrument and recorder, the weld portion of the above simulation test material was inspected.

First, initial setting of the probe was performed in the air. A test frequency was set at 500 kHz, X-coordinate was set at 0 V as an origin, and Y-coordinate was set at −1.5 V.

Next, an amplitude and a phase were adjusted by the eddy current test instrument so that amplitude is deflected by +1.5 V when the probe is placed on a base material (non-weld portion) of the simulation test material.

Under these conditions, the sound part and the part containing carbon steel mixed therein of the weld portion of the simulation test material were inspected.

With respect to the mixed part of a thin-walled test material having a wall thickness of 3 mm or 4 mm, since signal is deflected fully, the amplitude value was decreased by 6 dB or 12 dB, respectively.

The results are shown in Table 1. The values of X-coordinate and Y-coordinate of the amplitude of signal are designated as X-amplitude and Y-amplitude.

TABLE 1

| | | | X-amplitude (V) | Y-amplitude(V) |
|---|---|---|---|---|
| Base Material | | | 1.50 | 0.00 |
| Sound Part | Flat Plate | 3 | 0.28 | 0.41 |
| | Flat Plate | 4 | 0.47 | 0.86 |
| | Flat Plate | 5 | 0.98 | 0.98 |
| | Straight Pipe | 6.5 | 1.04 | 0.77 |
| | Straight Pipe | 7.1 | 1.04 | 0.83 |
| Mixed Part | Flat Plate | 3 | −0.52 | 2.36 |
| | Flat Plate | 4 | −0.36 | 2.87 |
| | Flat Plate | 5 | 0.43 | 3.08 |
| | Straight Pipe | 6.5 | 1.04 | 1.58 |
| | Straight Pipe | 7.1 | 1.15 | 1.59 |

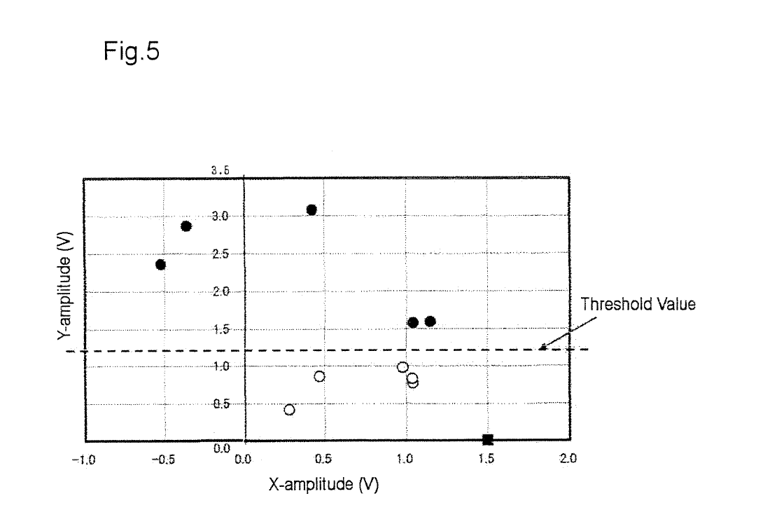

A master plot diagram was made based on the above results. The obtained master plot diagram is shown in FIG. 5. The base material indicated by the symbol “▪”, the sound part is indicated by the symbol “◯”, and the mixed part is indicated by the symbol “”.

The Y-amplitude was set at 1.25 V and the threshold value was indicated by a dotted line. The case where the Y-amplitude exhibits 1.25 V or more is discriminated that the carbon steel is mixed.

### DESCRIPTION OF REFERENCE NUMERALS

1: Excitation and inspection coil
2: Balance coil
3: Permanent magnet
4: Bobbin
5: Magnetic shielding

1. A method for inspecting an austenitic stainless steel weld, comprising:
performing eddy current test of a weld portion of an austenitic stainless steel using a probe comprising an inspection coil and a permanent magnet disposed inside the inspection coil, thereby detecting a foreign metallic material mixed into the weld portion.

2. The method for inspecting an austenitic stainless steel weld according to claim 1, wherein the foreign metallic material is carbon steel.

3. The method for inspecting an austenitic stainless steel weld according to claim 1, wherein magnetic flux density of magnetic field formed by the permanent magnet is from about 0.3 to about 1.5 tesla.
